(19) United States
(12) Patent Application Publication
(10) Pub. No.: US 2020/0388904 A1
(43) Pub. Date: Dec. 10, 2020

(54) METHOD AND DEVICE FOR EQUIPPING AN ANTENNA STRUCTURE WITH AN ELECTRONIC COMPONENT

(71) Applicant: Mühlbauer GmbH & Co. KG, Roding (DE)

(72) Inventor: Sigmund Niklas, Zell (DE)

(73) Assignee: Mühlbauer GmbH & Co. KG, Roding (DE)

(21) Appl. No.: 16/770,160

(22) PCT Filed: Dec. 11, 2018
(86) PCT No.: PCT/EP2018/084420

§ 371 Date: Jun. 5, 2020

(30) Foreign Application Priority Data
Dec. 12, 2017 (DE) 10 2017 129 625.5

(51) Int. Cl. H01Q 1/22; H01Q 1/38; H05K 3/28; H05K 3/12; H05K 1/09

(52) U.S. Cl. CPC H01Q 1/2225; H01Q 1/38; H05K 1/097; H05K 3/125; H05K 3/284

(57) ABSTRACT

A method and an apparatus are provided for the equipping of an antenna structure, in particular an RFID antenna structure, with an electronic component, in particular with an RFID chip. The method includes: (a) applying an electronic component to an antenna structure which is formed on a carrier substrate and which is made from a sinterable material that is electrically conductive after its sintering, so that a contact surface is formed between a contact region of the antenna structure and a corresponding electrical contact of the component; and (b) heating the antenna structure in order to sinter the same, thereby causing formation of an adhesive-free mechanical and electrical connection between the contact region of the antenna structure and the electrical contact of the component. The method can also be used to equip the antenna structure with a plurality of electronic components.

### CROSS-REFERENCE TO RELATED APPLICATIONS

This application is a national phase entry of, and claims priority to, International Application No. PCT/EP2018/084420, filed Dec. 11, 2018, which claims priority to German Patent Application No. 10 2017 129 625.5, filed Dec. 12, 2017. The above-mentioned patent applications are incorporated herein by reference in their entireties.

### TECHNICAL FIELD

This application relates to a method as well as an apparatus for the equipping of an antenna structure, such as an RFID antenna structure, with an electronic component, such as an RFID chip, as well as such an antenna structure equipped with at least one component and electrically and mechanically connected (hereinafter: antenna structure/component combination).

### BACKGROUND

In the context of this application, RFID stands for “Radio Frequency Identification” and refers to a well-known technology for transmitter-receiver systems for the automatic and contactless identification and localization of objects and living beings using radio waves. In the case of RFID, the antenna structure (antenna structure/component combination) which is connected to the electronic component (RFID chip) can, in particular, represent, or be part of, a RFID radio label, as it is referred to (often also referred to as an “RFID tag”). However, the invention described in the further application sections below is not limited to RFID applications but can also be used in connection with other technologies and applications.

Known antenna structures can be constructed so as to be self-supporting, such as for example conventional rod antennas made of metal, or conversely, in particular in the case of antennas for short-range radio communications, they can be applied to a carrier substrate, for example as a thin-film metallization. In order to form a radio module, an antenna structure must be provided with appropriate circuitry, which can be constructed in the form of an electronic component in the form of a radio chip. In order to connect the antenna structure, or its antenna contact, in conventional solutions for antenna structures applied to a carrier substrate (e.g. for RFID tags), an electrically conductive adhesive, e.g., on an epoxy basis, is typically applied to an antenna contact of the antenna structure and then the electronic component is placed on it. In addition, for the subsequent thermal curing of the adhesive, heated thermodes are typically used in order to press the component onto the antenna contact during curing, and so as to heat the adhesive.

It would therefore be desirable to provide a method as well as an apparatus for the improved equipping of an antenna structure, in particular an RFID antenna structure, with an electronic component, in particular an RFID chip, as well as a corresponding antenna structure/component combination.

### SUMMARY

To address these and other problems with conventional systems and designs, a method is provided in one embodiment of the invention for the equipping of an antenna structure, in particular an RFID antenna structure, with an electronic component, in particular with an RFID chip. The method includes the following steps: (i) applying an electronic component to an antenna structure which is formed on a carrier substrate and which is made from a sinterable material that is electrically conductive after its sintering, so that a contact surface is formed between a contact region of the antenna structure and a corresponding electrical contact of the component; and (ii) heating the antenna structure in order to sinter the same, and, caused thereby, with simultaneous formation of an adhesive-free mechanical and electrical connection between the contact region of the antenna structure and the electrical contact of the component. The method can also be used in order to equip the antenna structure with a plurality of electronic components.

An “antenna structure,” in the context of this application, is to be understood to mean a spatial-physical structure made of electrically conductive material, in particular a metal or a metal alloy, which is constructed as a radio antenna. The antenna structure may be formed on a carrier substrate, for example of paper or plastics material, in particular also as a thin layer.

An “electronic component,” in the context of this application, is to be understood to mean (i) an electronic passive or active individual component, (ii) an electronic circuit, in particular an integrated circuit (IC), or (iii) an assembly, such as a printed circuit (PCB, Printed Circuit Board), which comprises several individual components or electronic circuits. A contact of the component can thus be an electrically conductive contact pad or an electrically conductive contact surface on an individual component, on an integrated circuit or on an assembly.

A “sinterable material which is electrically conductive after its sintering” is to be understood to mean a material which contains fine-grained, electrically conductive particles, in particular metallic particles, and which, when it is heated to a (sintering) temperature which, however, remains below the melting temperature of the main components of the material so that the shape (form) of the workpiece (in this case the antenna structure) is retained, acquires its final properties, such as hardness, strength or electrical conductivity and/or thermal conductivity, without there being a need to apply pressure to the material. The material can be an electrical insulator before the sintering or only have a lower electrical conductivity when compared to its electrical conductivity after the sintering, so that the final electrical conductivity of the finished antenna structure is only achieved by the sintering.

With the help of the method in accordance with the order, it is possible to simplify the process for manufacturing the antenna structure/component combination, which can be used to achieve time and cost savings, among other things. When compared with a conventional manufacturing process, in particular individual manufacturing steps can be simplified or can even be omitted. The use of heated thermodes is no longer required for the final establishment of the connection between the antenna structure and the component, which in addition eliminates the associated risk of mechanical damage to the component. Likewise, the manufacturing step, previously used, of applying adhesive in order to fix the component to the antenna structure can be omitted.

In the following, preferred embodiments and further developments of the method will be described, each of which, as far as this is not expressly excluded, can be combined in any desired manner with one another, as well as with the other embodiments of the invention which are described in the following. The method is suitable for manufacturing an antenna structure/component combination, which is described in the following.

In accordance with some embodiments, before the component is applied, the antenna structure is first produced in the method by printing the antenna structure on the carrier substrate with a sinterable ink which contains electrically conductive particles for the formation of an electrical conductivity of the antenna structure, which is sintered by the subsequent heating. In this way, it is possible in a simple and highly flexible manner to form a wide variety of antenna structures on a corresponding carrier substrate without there being a need for them to be prefabricated in advance.

In accordance with further embodiments, the ink further contains an antioxidant (reducing agent). In this way, the conductive particles in the ink can be protected against material changes due to oxidation. In accordance with another embodiment, such an ink contains metallic nanoparticles (for example made of copper), a carrier agent (for example di(propylene glycol) methyl ether), as well as such an antioxidant (for example butylated hydroxytoluene (BHT), ascorbic acid or alkanethiols). A particularly suitable mixing ratio, based on the volume (100%) of the ink, is approx. 25-35% nanoparticles, approx. 65-75% carrier agent and less than 1% antioxidant. A mixing ratio of approx. 30% nanoparticles, approx. 70% carrier agent and less than 1% antioxidant is particularly preferred.

In accordance with further embodiments, the printing of the antenna structure onto the carrier substrate is carried out by an inkjet printer. This arrangement makes it possible to achieve a particularly high flexibility and variability with regard to the generation of a variety of different antenna structure shapes, since, unlike with classical screen printing for example, neither a prefabricated print mask needs to be produced nor is it necessary to replace the latter in order to produce different antenna structure shapes. In addition to achieving a correspondingly increased flexibility, this can also be used to reduce processing times and, accordingly, also production costs.

In accordance with additional embodiments, the method further includes one or more of the following heating steps: (i) prior to the application of the component, heating the antenna structure generated to a temperature which is below the sintering temperature of the ink in order to at least partially dry the ink and/or the carrier substrate; (ii) heating the ink in the region of the contact surface to a temperature which is below the sintering temperature of the ink for preliminary adhesive-free mechanical connection of the component with the antenna structure. The heating step (i) can serve to dry the ink or the carrier substrate after the ink has been applied to the carrier substrate to such an extent that, during the subsequent application of the electronic component to the printed antenna structure, this does not cause any undesirable changes in the shape of the antenna structure, for example due to smudging or displacement of ink that is still liquid, or undesirable deformations of the carrier substrate that is still wet. The heating step (ii), on the other hand, can be used, as already mentioned, in order to establish a temporary adhesive-free mechanical connection of the component with the antenna structure. In this context, the preliminary mechanical connection is achieved by further drying of the ink, so that, as a result of this, at least a weak adhesion of the component to the antenna structure results at its surface area which is wetted with the ink (i.e., at the contact surface).

A “sintering temperature” is to be understood in the context of this application to mean a temperature above which the sintering of the ink (under otherwise normal conditions) begins, if only for temperature reasons (i.e., also without the application of pressure). The temperature actually used for sintering in the method represents a sintering temperature in the context of this application.

In accordance with further embodiments, during heating of the antenna structure for sintering of the same, the antenna structure is heated to a temperature (sintering temperature) of at least 250° C., preferably at least 300° C., at least in the region of the contact surface. Preferably, during the course of this, a temperature of 350° C. is not exceeded. It has been found that this temperature range is particularly suitable, on the one hand, for causing sintering of the ink and, on the other hand, for keeping the temperature-related stress on the electronic component as well as the carrier substrate with the antenna structure as low as possible and thus to avoid the impairments or damage resulting from this.

In accordance with other embodiments, the application of the component to the antenna structure is carried out either by (i) direct transfer of the component from a component carrier substrate to the antenna structure (e.g., via DDA, or “direct die attachment”); or by (ii) indirect transfer of the component from a component carrier substrate to the antenna structure by a transfer device, which takes the component from the component carrier substrate, for example a semiconductor wafer or a component carrier (e.g., tape or tray), transports it to the antenna structure and applies it to the antenna structure. While embodiment (i) can provide advantages in terms of cost and speed, embodiment (ii) is particularly advantageous when not only a single type of component is to be processed, or when the width of the carrier substrate exceeds the effective width of the component carrier, so that a direct transfer would be possible only with difficulties, or even not possible at all.

In accordance with some embodiments, the method further involves encapsulating the electronic component after making its mechanical and electrical connection to the antenna structure. In this way, the component is protected from undesirable external influences by the encapsulation. The mechanical stability of the resulting antenna structure/component combination can also be increased in this way. In accordance with a preferred variant to this, the encapsulating is carried out in a contactless manner by the application of a liquid or paste-like encapsulation compound onto the component and subsequent curing thereof. In this way, the encapsulating can be carried out by the Globe Top technology, which is known from the manufacture of semiconductor components, in which a liquid or a paste-like encapsulation compound is applied onto the semiconductor component (chip, bare die) and then cured thermally or, preferably, by irradiation with ultraviolet light.

In accordance with further embodiments, in the method, a sensor-based inspection of the antenna structure and/or of the component is also carried out at at least one point in time during the course of the method. The further course of the method is then controlled in dependence upon the result of this sensor-based inspection. In this way, the further course of the method, in particular also the use of initial components, such as for example the material of the antenna structure, of the electronic components and/or of the encapsulation compound in the case of encapsulation being performed, can be controlled in dependence on whether, in a preceding method step, a production fault has occurred, as a result of which the manufacture of a fault-free product (antenna structure/component combination) on the basis of the inspected, possibly already equipped antenna structure can no longer be expected. In this way, it is possible to detect production faults and to eject corresponding faulty production results, to optimize the use of materials and to optimize throughput times.

The method can be defined, in accordance with a particular embodiment, in such a way that if a production fault has been detected according to the result of the inspection, the further course of the method is controlled in such a way that at least one method step of the method which is envisaged for the manufacture of a fault-free antenna structure/component combination according to the method is omitted. For example, the application of the electronic component to the antenna structure can be omitted if, by the inspection, the antenna structure has previously been detected as being defective. In a similar manner, one or more method steps following the application of the component can be omitted. For example, the encapsulating can be omitted if the inspection has shown that the component which has been applied to the antenna structure is defective.

In accordance with further embodiments, the carrier substrate is constructed so as to be in the form of a tape and is transported along its longitudinal direction. A plurality of antenna structures are provided or generated on the carrier substrate along a second direction which runs at an angle to the longitudinal direction, so that a multi-track manufacturing process or equipping process for manufacturing a quantity of antenna structure/component combinations which are distributed accordingly over several tracks results along the transport direction. In this way it is possible to process a plurality of antenna structures or antenna structure/component combinations in parallel in at least one method step, preferably in every method step, which can be used for an increase in efficiency when compared with a process with purely serial processing.

In another embodiment of the invention, an apparatus is provided for equipping an antenna structure, in particular an RFID antenna structure, with an electronic component, in particular with an RFID chip. The apparatus is arranged to carry out the method as described above, preferably in accordance with one or more of its embodiments described herein. All of what has been mentioned above in relation to the method thus also applies to the apparatus accordingly.

In accordance with some embodiments, the apparatus comprises an equipping device and a sintering device. The equipping device is configured to place an electronic component on an antenna structure which is formed on a carrier substrate, which antenna structure is made of a sinterable material that is electrically conductive after its sintering, in such a way that a contact surface is formed between a contact region of the antenna structure and a corresponding electrical contact of the component. The sintering device is configured to heat the antenna structure in order to sinter it while thereby simultaneously causing an adhesive-free mechanical and electrical connection between the contact region of the antenna structure and the electrical contact of the component to be formed.

In accordance with various embodiments, the equipping device comprises a first transfer device which is configured in order to directly transfer a component from a carrier substrate to the antenna structure and/or a second transfer device which is configured in order to indirectly transfer a component from a carrier substrate to the antenna structure. In this context, the second transfer device, if present, is in turn configured to take the component from a carrier substrate, to transport it to the antenna structure, and to apply it to the antenna structure.

In accordance with further embodiments, the apparatus further includes one or more of the following devices: (i) a printing device which is configured to generate the antenna structure, prior to the application of the component, by printing the antenna structure onto the carrier substrate by a sinterable ink which contains electrically conductive particles, in particular nanoparticles, to form an electrical conductivity of the antenna structure by sintering by the sintering device; (ii) a drying device which is configured to heat the antenna structure which has been generated, to a temperature which is below the sintering temperature of the material of the antenna structure for at least partial drying of the ink and/or of the carrier substrate prior to the application of the component; (iii) a fixing device which is configured to heat the ink in the region of the contact surface to a temperature which is below the sintering temperature of the ink for preliminary adhesive-free mechanical connection of the component to the antenna structure; (iv) an encapsulating device which is configured to encapsulate the electronic component after its mechanical and electrical connection to the antenna structure has been established; (v) a sensor device for the sensor-based inspection of the antenna structure and/or of the component at at least one point in time during the course of the method, as well as a control device for controlling or feed-back controlling the further course of the method as a function of the result of this sensor-based inspection; (iv) a buffer device which is configured to buffer the carrier substrate between two successive ones of the devices of the apparatus; (vii) a testing device for testing the completed antenna structure/component combination; and (viii) a separating device for separating the antenna structure/component combinations which have been produced on a common carrier substrate.

In the context of this application, the term “configured” is to be understood to mean that the corresponding apparatus or device is set up to perform a specific function. The configuration can in this respect be carried out, for example, by a corresponding setting of parameters of a course of a process or of switches or the like for activating or deactivating functionalities or settings. The apparatus may have several predetermined configurations or modes of operation, so that the configuring can be carried out by a selection of one of these configurations or modes of operation.

Accordingly, the drying device, the fixing device as well as the sintering device are each provided to heat the antenna structure or the antenna structure/component combination, so that at least two or more of these devices can also be constructed as a unit, for example so that, with the use of dual-use components, it is possible to implement a particularly efficient solution or a solution which is optimized as regards the use of space.

In another embodiment of the invention, an antenna structure is provided, in particular an RFID antenna structure, with an electronic component which is connected thereto, in particular an RFID chip. The antenna structure is formed on a carrier substrate and is made of a sintered electrically conductive material. It is connected, at a contact surface between a contact region of the antenna structure and a corresponding electrical contact of an electronic component by an adhesive-free mechanical and electrical connection which is formed by the sintered material, to the component. This antenna structure/component combination can be manufactured by the method described above and/or with an apparatus as described above.

### BRIEF DESCRIPTION OF THE DRAWINGS

The accompanying drawings, which are incorporated in and constitute a part of this specification, illustrate one or more embodiments of the invention and, together with the general description given above and the detailed description given below, explain the one or more embodiments of the invention.

FIG. 1 is a schematic flow chart illustrating one embodiment of the method in accordance with the invention.

FIG. 2 illustrates different intermediate states of an antenna structure/component combination to be manufactured, which occur during its manufacture in accordance with the method of FIG. 1.

FIG. 3 is a block diagram illustrating in schematic form an embodiment of the apparatus in accordance with the invention.

In these figures, the same reference signs are used throughout for the same elements of the invention or for elements of the invention corresponding to one another.

### DETAILED DESCRIPTION

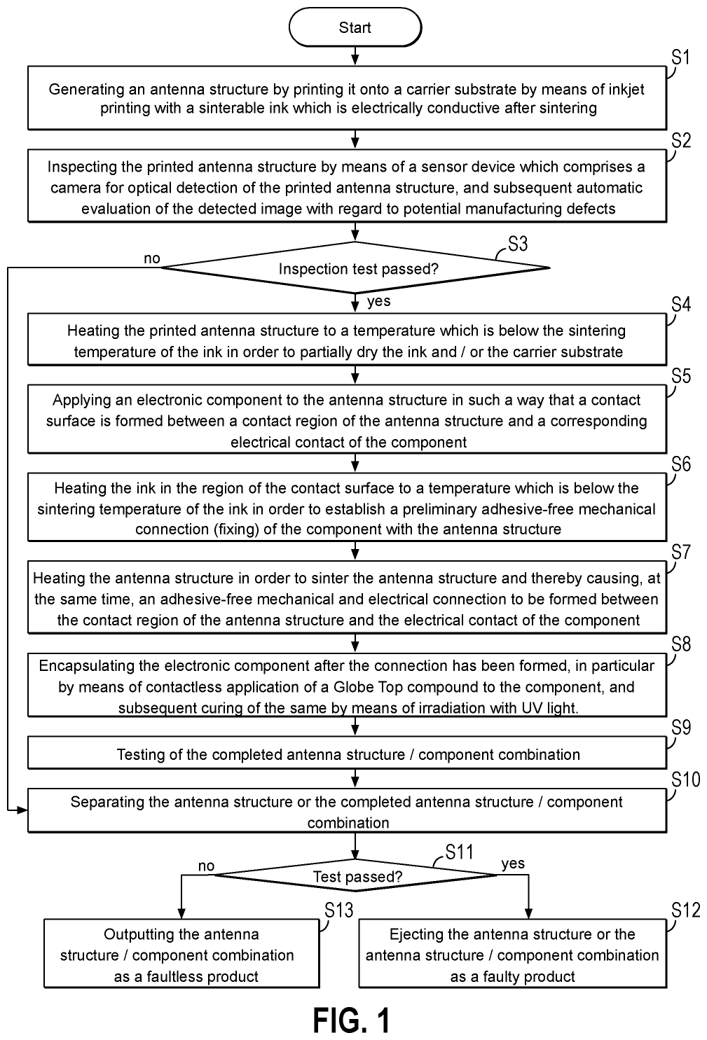

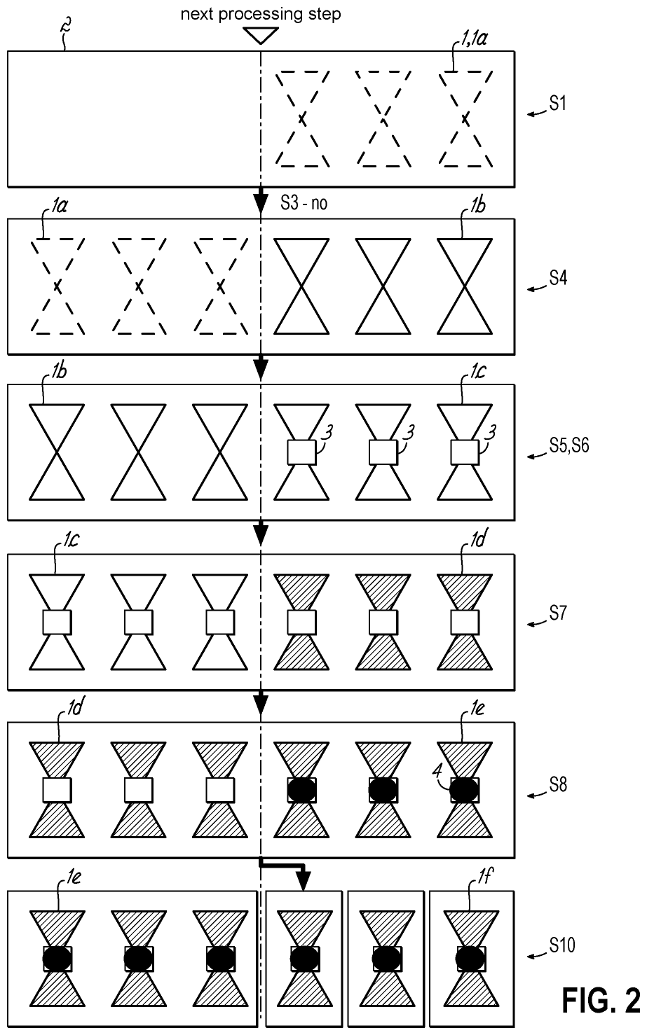

First, with reference to FIGS. 1 and 2, one embodiment of the method or the process in accordance with the invention will be explained. The method comprises a step S1 in which an antenna structure 1 or 1a is generated by printing it onto a carrier substrate 2. In this context, an inkjet printer is preferably used for printing. The ink which is used is a sinterable ink which, at least after its sintering, is electrically conductive. For this purpose, in addition to a liquid or paste-like carrier substance, the ink preferably contains metallic nanoparticles, e.g., of copper, as well as preferably an antioxidant (reducing agent) as corrosion protection for the nanoparticles. In FIG. 2, the carrier substrate is constructed as a tape on which a row (track) of antenna structure/component combinations is generated along its longitudinal extent or longitudinal direction (single-track process). As an alternative, further antenna structures can also be generated on the carrier substrate in one or more tracks in a direction which is at an angle, in particular at a right angle, to the longitudinal direction, so that, overall, this results in a multi-track process and one which, in this sense, is parallelized.

In the multi-track manufacturing or equipping process, at least one of the following devices may be displaceable in a motorized manner in the longitudinal direction and/or in the second direction which is at an angle to the longitudinal direction in order to process several rows with one device: printer 11, camera 12, encapsulating device 17 and testing device 18. The drying device 13a, 13b, the fixing device 15 and the sintering device 16a, 16b can be adapted for the multi-track process, in particular by a correspondingly wide construction covering several tracks. Here, the term “direction” also respectively includes the corresponding opposite direction, so that the motor-driven displacement can take place, for example, both along the transport direction of the carrier substrate as well as in the opposite direction, i.e., against the transport direction. In addition, the latter may also be provided in the case of an apparatus for the operation in a purely single-track manner or in the case of an apparatus that can at least be configured for the operation in a single-track manner.

This is followed by a step S2, in which the freshly printed antenna structure S1a is automatically inspected in a sensor-based manner, in particular by image evaluation, with regard to potential manufacturing defects, in particular printing defects (inspection test). In a further step S3, the process sequence is branched off depending on whether a manufacturing defect was detected during the inspection test or, conversely, whether the inspection test was passed. In the case of a defect (S3—no), the method jumps directly to a separation step S10, in which a separation of the antenna structure 1a by a corresponding cut of the carrier substrate 2 takes place, omitting further manufacturing steps S4 to S9, which are provided for the fault-free case. Since the inspection test was not passed, in the subsequent step S11, the method branches off to an ejection step S13 (S11—no), in which the defective antenna structure 1a is ejected from the process as a faulty product. If, on the other hand, the inspection test is passed in the step S2 (S3—yes), a drying step S4 follows, in which the printed antenna structure 1a is heated to a temperature which is below the sintering temperature of the ink in order to dry the ink and/or the carrier substrate partially, but not yet completely, so that this results in a partially dried antenna structure 1b.

Then, in a step S5, an electronic component 3, for example an RFID chip, is applied to the partially dried antenna structure 1b in such a way that, as a result of this, a contact surface is formed between a contact region of the antenna structure 1b and a corresponding electrical contact of the component 3, in particular a contact pad on the chip. Here, the chip is typically applied as a bare die, as it is referred to, so that this then results in an already assembled antenna structure 1c. In a further step S6, the ink is then heated in the region of the contact surface to a temperature which is below the sintering temperature of the ink in order to establish a preliminary adhesive-free mechanical connection (fixing) of the component 3 with the antenna structure 1c. This step S6 is optional, and can also be carried out simultaneously, or at least substantially simultaneously, with the step S5. In the step S6, the fixing is achieved by further drying of the ink so that an adhesion between the applied component 3 and the antenna structure 1c results, which adhesion provides a protection against an undesired displacement of the component relative to the antenna structure during the further course of the method until the component 3 is finally fixed to the antenna structure.

In a further step S7, the antenna structure 1c is then heated to a sintering temperature in order to sinter the antenna structure 1c, and, caused thereby, at the same time an adhesive-free mechanical and electrical connection between the contact region of the antenna structure 1c and the electrical contact of the component 3 is formed, in particular reinforced. The material properties of the antenna structure 1c are changed by the sintering. During this sintering, the metallic nanoparticles are baked together in such a way that the sintered antenna structure 1d has a sufficiently high electrical conductivity which is required for the desired antenna function. In addition, the mechanical connection or adhesion of the component to the antenna structure 1d is also further strengthened by this.

This is followed by a step S8, in which the electronic component 3 is provided with a housing 4 (encapsulation) by contactless application of an encapsulation compound (e.g., Globe Top) and curing of the same by irradiation with UV light. The thus completed antenna structure/component combination 1e is then tested in a step S9, in particular as regards a correct functioning and/or whether it is otherwise free from defects. This is followed by the separation step S10 already mentioned, for separating the antenna structure/component combination 1e, as far as this was initially manufactured together with others on a common carrier substrate. If a defect is detected in the test from step S9 (S11—no), the process again branches back to the step S13 already described and the defective antenna structure/component combination is ejected. Otherwise, if the test has been passed successfully (S11—yes), the now completed faultless antenna structure/component combination if is output as a faultless product in an output step S12. The use of the separation step may also be optional, in particular in dependence upon the format of the carrier substrate used. For example, in the case of a carrier substrate in the form of a tape, either the separation step can be used or, alternatively, the carrier substrate including its fault-free assembled antenna structures as well as, if applicable, its faulty antenna structures—either having been equipped or not—can be wound up.

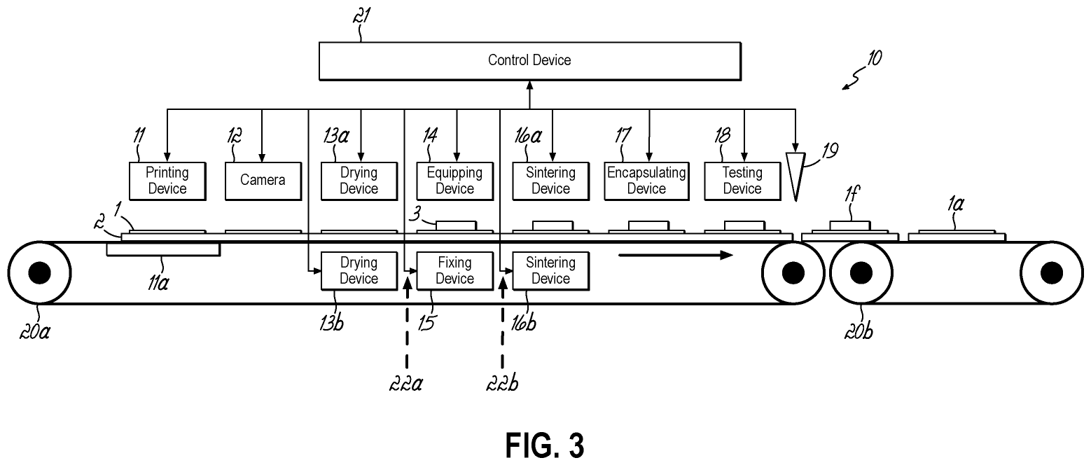

FIG. 3 shows a preferred embodiment of the apparatus 10 in accordance with the invention, which can be used to carry out the method shown in FIGS. 1 and 2. In the example shown, the carrier substrate 2 is constructed as a tape on which a plurality of antenna structures 1, each equipped with an electronic component 3, are to be produced. For this purpose, the tape 2 is transported by a transport device 20a in the form of a conveyor belt through the apparatus 10 (from left to right in FIG. 3).

The apparatus 10 has a printing device 11, which is set up to carry out the step S1 (compare below FIG. 1 and—as far as relevant—FIG. 2 with regard to the steps mentioned here). A support 11a is provided spatially opposite to it in order to support the carrier substrate 2 during the printing process. A sensor device 12 with a camera for the visual inspection (step S2) of the antenna structures 1 freshly printed on the carrier substrate 2 by the printing device 11 follows downstream along the transport direction of the carrier substrate 2. This is followed by a drying device in two parts 13a, 13b, which heats the carrier substrate 2 on both sides in order to partially dry it (step S4), the carrier substrate 2 having the antenna structure 1 printed on it. An equipping device 14 is provided in order to equip the antenna structure 1 with an electronic component 3 by applying it thereto (step S5). Optionally, a fixing device 15 can additionally be provided, in particular at the same place, which serves to further dry the ink with component 3 already applied, in order to effect a preliminary fixing of the component 3 to the antenna structure 1 (step S6). The fixing device 15 may be arranged below the equipping position or the equipping device. In the case of the equipping being carried out in the DDA process, the fixing device 15 can optionally be constructed together with the DDA equipping device 14 as an integrated separate machine module which is integrated into the apparatus 10 by buffer devices 22a, 22b.

This is followed, along the transport direction, by a sintering device 16a, 16b, with heating elements which are provided on both sides of the carrier substrate 2 in order to heat the antenna structure, which has already been equipped, to a sintering temperature of the ink for the purpose of sintering the antenna structure 1 (step S7). Downstream thereof, this is followed by an encapsulating device 17, which is set up to apply a suitable encapsulation compound in liquid or paste-like form onto the component 3 in a non-contact manner, i.e., without there being any mechanical contact between the encapsulating device 17 and the component 3, and to cure it there, in particular by irradiation with UV light (step S8).

In addition, or as an alternative to the encapsulating of the electronic component, the assembled antenna structure can be coated with a UV-curing lacquer e.g., to a thickness of 10-50 μm, e.g., by printing, potting or spraying, by a coating device (not shown), either before or, preferably, after the sintering device 16a/16b. In that case the ink does not necessarily have to contain an antioxidant. The lacquer provides protection for the antenna structure against mechanical damage.

A testing device 18 is located downstream of the encapsulating device 17, which testing device 18 serves to test the already completed antenna structure/component combination, in particular with regard to optically detectable damage or defects and/or its functional capability (step S9). Finally, a separating device 19 follows, which is set up to separate individual antenna structure/component combinations 1f, which can be constructed as RFID labels, from the carrier substrate 2 in the form of a tape (step S10).

A control unit 21 is provided in order to control the entire system. The control unit 21 is set up, in conjunction with the sensor device 12, to prevent further processing, if a defect in a freshly printed antenna structure 1a has been detected by the sensor device 12 (step S3—no), of this defective antenna structure 1a at the devices 13a, 13b to 18, and to eject the defective antenna structure 1a as a faulty product (step S13). It is also set up, in dependence upon the result of the test (step S11) by the testing device 18, either to output the completed antenna structure/component combination if as a faultless product (step S12) or otherwise to eject it as a faulty product (step S13). The control device 21 may comprise an input means and a display screen. Using an input mask on the screen, the operator can select the ambient conditions in which the antenna structure 1 is to be used, which type of ink is present, the characteristic quantity/quantities (size of the antenna, impedance, detection range, resonant frequency, etc.) which the antenna structure 1 is meant to have, or which antenna geometries can be printed with an available quantity of ink, in order for as many antenna structures 1 as possible to be able to be printed. By entering one or more parameters, suitable antenna structures 1 are calculated for the operator and suggested to the operator. In addition, the printing device 11, the transport devices 20a, 20b, the drying device 13a, 13b, the fixing device 15 and the sintering device 16a, 16b can each be adapted to the selected antenna structure 1 by the control system, e.g., by reducing the transport speed for the purpose of a longer sintering time in case the ink is applied in a thick layer. This can advantageously be used to achieve a higher level of automation, an increase in efficiency, less downtime in order to adjust settings on the machine, and a reduction in the amount of faulty products that occurs until the apparatus 10 is correctly adjusted by hand.

Finally, one or more buffer devices or buffer areas 22a, 22b can optionally be provided, in which the respective intermediate product is “buffered” for a predetermined period of time or a predetermined transport section without further process protection before it is fed to the next process step. This can be useful after the drying in the drying device 13a, 13b or after the equipping or fixing respectively at the equipping device 14 or the fixing device 15, in order to give the respective intermediate product a sufficient amount of time for an after-effect of the preceding process step (in particular for the drying of the ink and/or the carrier substrate which has become wet as a result).

While at least one example embodiment has been described above, it is to be noted that there are a large number of variations to this. It is also to be noted that the example embodiments which have been described only represent non-limiting examples, and it is not intended to thereby limit the scope, the applicability or the configuration of the devices and methods described here. Rather, the preceding description will provide the skilled person with instructions for the implementation of at least one example embodiment, whereby it is understood that various changes can be made as regards the functionality and the arrangement of the elements described in an example embodiment without deviating from the subject matter respectively defined in the appended claims, as well as their legal equivalents.

1. A method for the equipping of an antenna structure with an electronic component, wherein the method comprises:
applying of the electronic component to the antenna structure which is formed on a carrier substrate and which is made from a sinterable material that is electrically conductive after sintering, so that a contact surface is formed between a contact region of the antenna structure and a corresponding electrical contact of the electronic component;
heating the antenna structure to sinter same, with simultaneous formation of an adhesive-free mechanical and electrical connection between the contact region of the antenna structure and the electrical contact of the electronic component.

2. The method of claim 1, further comprising:
producing the antenna structure, prior to the step of applying of the electronic component, by printing the antenna structure on the carrier substrate by a sinterable ink which contains electrically conductive particles for the formation of an electrical conductivity of the antenna structure, which is sintered by the subsequent heating step.

3. The method of claim 2, wherein the ink further contains an antioxidant.

4. The method of claim 2, wherein the printing of the antenna structure onto the carrier substrate is carried out by an inkjet printer.

5. The method of claim 2, further comprising at least one of the following heating steps:
prior to the step of applying of the electronic component, heating the antenna structure generated to a temperature which is below the sintering temperature of the ink in order to at least partially dry the ink and/or the carrier substrate; and
heating the ink in a region of the contact surface to a temperature which is below the sintering temperature of the ink for preliminary adhesive-free mechanical connection of the electronic component with the antenna structure.

6. The method of claim 1, wherein, during heating of the antenna structure for sintering, the antenna structure is heated to a temperature of at least 250° C. at least in a region of the contact surface.

7. The method of claim 1, wherein the step of applying of the electronic component to the antenna structure is carried out by one of:
direct transfer of the electronic component from a component carrier substrate to the antenna structure; and
indirect transfer of the electronic component from the component carrier substrate to the antenna structure by a transfer device, which takes the electronic component from the component carrier substrate, transports the electronic component to the antenna structure and applies the electronic component to the antenna structure.

8. The method of claim 1, further comprising:
encapsulating the electronic component after making its mechanical and electrical connection to the antenna structure.

9. The method of claim 8, wherein the step of encapsulating is carried out in a contactless manner by application of a liquid or paste-like encapsulation compound onto the electronic component and subsequent curing thereof.

10. The method of claim 1, further comprising:
a sensor-based inspection of at least one of the antenna structure and the electronic component along at least one point in time during the course of the method; and
controlling of subsequent steps of the method in dependence upon a result of the sensor-based inspection.

11. The method of claim 10, wherein, if a production fault has been detected according to the result of the inspection, the subsequent steps of the method are controlled in such a way that at least one method step of the method which is envisaged for the manufacture of a fault-free antenna structure/component combination is omitted.

12. The method of claim 1, wherein:
the carrier substrate is constructed in the form of a tape and is transported along a longitudinal direction thereof; and
a plurality of antenna structures are provided or generated on the carrier substrate along a second direction which runs at an angle to the longitudinal direction, so that a multi-track manufacturing process for manufacturing a quantity of antenna structure/component combinations which are distributed accordingly over several tracks results along a transport direction.

13. The method of claim 3, wherein the printing of the antenna structure onto the carrier substrate is carried out by an inkjet printer,
wherein the method further comprises at least one of the following heating steps:
prior to the step of applying of the electronic component, heating the antenna structure generated to a temperature which is below the sintering temperature of the ink in order to at least partially dry the ink and/or the carrier substrate; and
heating the ink in a region of the contact surface to a temperature which is below the sintering temperature of the ink for preliminary adhesive-free mechanical connection of the electronic component with the antenna structure;
wherein, during heating of the antenna structure for sintering, the antenna structure is heated to a temperature of at least 250° C., at least in a region of the contact surface,
wherein the step of applying of the electronic component to the antenna structure is carried out by one of:
direct transfer of the electronic component from a component carrier substrate to the antenna structure; and
indirect transfer of the electronic component from the component carrier substrate to the antenna structure by a transfer device, which takes the electronic component from the component carrier substrate, transports the electronic component to the antenna structure and applies the electronic component to the antenna structure;
wherein the method further comprises encapsulating the electronic component after making its mechanical and electrical connection to the antenna structure;
wherein the step of encapsulating is carried out in a contactless manner by application of a liquid or paste-like encapsulation compound onto the electronic component and subsequent curing thereof;
wherein the method further comprises:
a sensor-based inspection of at least one of the antenna structure and the electronic component along at least one point in time during the course of the method; and
controlling of subsequent steps of the method in dependence upon a result of the sensor-based inspection;
wherein, if a production fault has been detected according to the result of the inspection, the subsequent steps of the method are controlled in such a way that at least one method step of the method which is envisaged for the manufacture of a fault-free antenna structure/component combination is omitted;
wherein the carrier substrate is constructed in the form of a tape and is transported along a longitudinal direction thereof; and
wherein a plurality of antenna structures are provided or generated on the carrier substrate along a second direction which runs at an angle to the longitudinal direction, so that a multi-track manufacturing process for manufacturing a quantity of antenna structure/component combinations which are distributed accordingly over several tracks results along a transport direction.

14. An apparatus for equipping an antenna structure with an electronic component, comprising:
an equipping device which is configured to place the electronic component on the antenna structure which is formed on a carrier substrate, the antenna structure being made of a sinterable material that is electrically conductive after sintering, in that a contact surface is formed between a contact region of the antenna structure and a corresponding electrical contact of the electronic component; and
a sintering device which is configured to heat the antenna structure to sinter the antenna structure while thereby simultaneously causing an adhesive-free mechanical and electrical connection between the contact region of the antenna structure and the electrical contact of the electronic component to be formed,
wherein the apparatus is configured to carry out a method for equipping the antenna structure with the electronic component.

15. The apparatus of claim 14, wherein the equipping device comprises at least one of:
a first transfer device which is configured to directly transfer a component from a carrier substrate to the antenna structure; and
a second transfer device which is configured to indirectly transfer the electronic component from a carrier substrate to the antenna structure, wherein the second transfer device is configured to take the electronic component from a carrier substrate, to transport the electronic component to the antenna structure, and to apply the electronic component to the antenna structure.

16. The apparatus of claim 14, further comprising at least one of:
a printing device which is configured to generate the antenna structure, prior to the application of the electronic component, by printing the antenna structure onto the carrier substrate by a sinterable ink which contains electrically conductive particles, to form an electrical conductivity of the antenna structure by sintering by the sintering device;
a drying device which is configured to heat the antenna structure which has been generated to a temperature which is below a sintering temperature of the material of the antenna structure for at least partial drying of the ink and/or of the carrier substrate prior to the application of the electronic component;
a fixing device which is configured to heat the ink in a region of the contact surface to a temperature which is below the sintering temperature of the ink for preliminary adhesive-free mechanical connection of the electronic component to the antenna structure;
an encapsulating device which is configured to encapsulate the electronic component after mechanical and electrical connection to the antenna structure has been established;
a sensor device for sensor-based inspection of at least one of the antenna structure and the electronic component along at least one point in time during the method, as well as a control device for controlling subsequent steps of the method as a function of the sensor-based inspection;
a buffer device which is configured to buffer the carrier substrate between two successive ones of the devices of the apparatus;
a testing device for testing the completed antenna structure/component combination;
a separating device for separating the antenna structure component combinations which have been produced on a common carrier substrate.

17. An RFID antenna structure, with an electronic component in the form of an RFID chip, wherein the antenna structure:
is formed on a carrier substrate and is made of a sintered electrically conductive material; and
is connected, at a contact surface between a contact region of the antenna structure and a corresponding electrical contact of an electronic component by an adhesive-free mechanical and electrical connection which is formed by the sintered material, to the electronic component.
